(19) United States
(12) Patent Application Publication
(10) Pub. No.: US 2025/0220935 A1
(43) Pub. Date: Jul. 3, 2025

(54) ELECTROSTATIC DEVICE

(71) Applicant: GlobalFoundries Singapore Pte. Ltd., Singapore (SG)

(72) Inventors: Jie Zeng, Singapore (SG); Kyong Jin Hwang, Singapore (SG)

(21) Appl. No.: 18/397,008

(22) Filed: Dec. 27, 2023

(51) Int. Cl. H01L 29/735; H01L 29/06; H01L 29/66

(52) U.S. Cl. CPC H10D 10/60; H10D 10/061; H10D 62/115

(57) ABSTRACT

The present disclosure relates to semiconductor structures and, more particularly, to electrostatic devices and methods of manufacture. The structure includes: a device having a collector region, an emitter region, and a base region; an oxidation structure within the base region; and an isolation structure abutting the oxidation structure and extending between the base region and the emitter region.

### BACKGROUND

The present disclosure relates to semiconductor structures and, more particularly, to electrostatic devices and methods of manufacture.

For more efficient power delivery in electric systems such as an electric vehicle, operation voltage is becoming higher and higher. And as integrated circuits continue to shrink in size, they become more sensitive to electrostatic discharge. This high voltage usage and continued scaling of devices require an electrostatic device (ESD) protection device with the capability of sustaining such high voltage with sufficient enough robustness in a small footprint.

Conventionally, a method of stacking low voltage ESD devices have been used to achieve high voltage operation capability. But the stacking method multiplies the ESD device footprint by the stacking number. Also, the use of multiple ESD devices results in an increased turn-on resistance.

### SUMMARY

In an aspect of the disclosure, a structure comprises: a device having a collector region, an emitter region, and a base region; an oxidation structure within the base region; and an isolation structure abutting the oxidation structure and extending between the base region and the emitter region.

In an aspect of the disclosure, a structure comprises: a collector region comprising a P− drift region in a semiconductor substrate; an emitter region comprising a P+ diffusion region in an N-well and a shallow trench isolation structure adjacent to the P+ diffusion region; a base region within an N-drift region in the semiconductor substrate; and a local oxidation in the base region, extending from the P− drift region and contacting the shallow trench isolation structure.

In an aspect of the disclosure, a method comprises: forming a device having a collector region, an emitter region, and a base region; forming an oxidation structure within the base region; and forming an isolation structure abutting the oxidation structure and extending between the base region and the emitter region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIGS. 2-5 show additional structures and respective fabrication processes in accordance with aspects of the present disclosure.

FIG. 6 shows a process flow representative of fabrication processes for manufacturing the devices of FIGS. 1-5.

### DETAILED DESCRIPTION

The present disclosure relates to semiconductor structures and, more particularly, to electrostatic devices and methods of manufacture. More specifically, the present disclosure relates to high voltage electrostatic device (ESD) protection devices. In embodiments, the high voltage ESD protection devices comprise a high voltage PNP bipolar transistor with a shallow trench isolation structure abutting a raised oxidation structure, i.e., LOCOS structure, inside a base region. Advantageously, the high voltage ESD protection devices exhibit a small footprint which can sustain high voltage operation, in addition to exhibiting a small turn-on resistance and increased breakdown voltage at higher temperatures.

The electrostatic devices of the present disclosure can be manufactured in a number of ways using a number of different tools. In general, though, the methodologies and tools are used to form structures with dimensions in the micrometer and nanometer scale. The methodologies, i.e., technologies, employed to manufacture the electrostatic devices of the present disclosure have been adopted from integrated circuit (IC) technology. For example, the structures are built on wafers and are realized in films of material patterned by photolithographic processes on the top of a wafer. In particular, the fabrication of the electrostatic devices uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

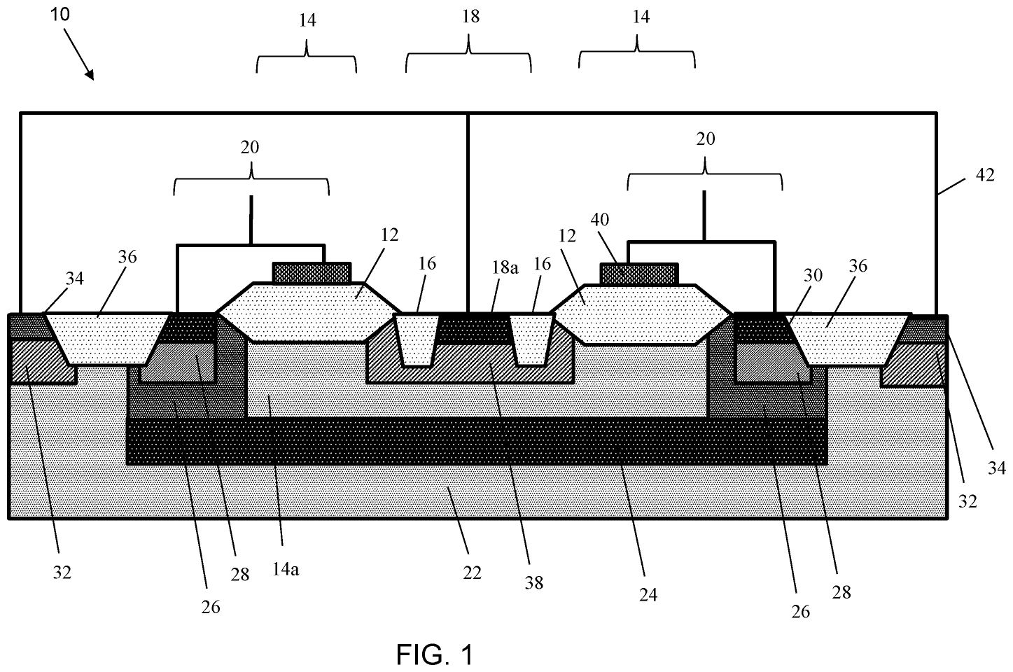

FIG. 1 shows a structure and respective fabrication processes according to aspects of the present disclosure. In embodiments, the structure 10 may be a high voltage PNP device with a local oxidation (LOCOS) 12 in a base region 14 abutting a shallow trench isolation structure 16. The shallow trench isolation structure is between a diffusion region in an emitter region 18 and the base region 14. In embodiments, the PNP device may be a lateral device comprising the emitter region 18, the base region 14 and a collector region 20. It should also be understood by those of skill in the art that the structure 10 may be an NPN device by simply changing the N-regions and P− regions to P− regions and N-regions, respectively.

More specifically, the structure 10 includes a semiconductor substrate 22. In embodiments, the semiconductor substrate 22 may be an epitaxial grown N-type semiconductor substrate. The semiconductor substrate 22 may be composed of any suitable material including, but not limited to, Si, SiGe, SiGeC, SiC, GaAs, InAs, InP, and other III/V or II/VI compound semiconductors. In embodiments, the semiconductor substrate 22 may comprise any suitable crystallographic orientation (e.g., a <100>, <110>, <111>, or <001> crystallographic orientation).

A buried isolation layer 24 may be formed in the semiconductor substrate 22. A drift region 26 may be formed in the semiconductor substrate 22, extending to and contacting the buried isolation layer 24. The buried isolation layer 24 may be a P+ region and the drift region 26 may be a p-type drift region. In embodiments, the combination of the buried isolation layer 24 and the drift region 26 may be used to isolate an N+ drift region 14a, e.g., in the base region 14, the emitter 18 and the collector 20.

FIG. 1 further shows a P− well 28 formed in the p-drift region 26 and a P+ region 30 (e.g., contact) formed in the P− well 28. An N-well 32 with an N+ region (e.g., contact) 34 may also be formed in the semiconductor substrate 22. In embodiments, the N-well 32 with N+ region 34 may be isolated from the P− drift region 26, P− well 28, and P+ region 30 (e.g., contact) by a shallow trench isolation structure 36 formed in the semiconductor substrate 22. The P+ region (e.g., contact) 18a may be formed in an N-well 38 within the drift region 14a. The shallow trench isolation structure 16 directly abuts (e.g., physically contacts) the LOCOS 12. The shallow trench isolation structure 16 may also isolate the P+ region (e.g., contact) 18a. In embodiments, the shallow trench isolation structure 16 is between the P+ diffusion region 18a in an emitter region 18 and the base region 14.

Polysilicon material 40 may be formed on the LOCOS 12. The polysilicon material 40 may be p-type polysilicon material. In embodiments, the polysilicon material is in the collector region 20, electrically connecting to the P+ region 30.

As should be understood by those of skill in the art, the emitter region 18 may comprise the P+ region 18a with the shallow trench isolation structure 16. Additionally, the base region 14 may comprise the N+ drift region 14a and the N-well 30. The collector region 20 may comprise polysilicon material 40, P− drift region 26, P− well 28, P+ region 30. In this way, the emitter region 18, the base region 14 and the collector region 20 form a PNP bipolar junction transistor.

The buried isolation layer 24, P− drift region 26, P− well 28, P+ regions (contacts) 18a, 30, drift region 14a, N-well 32, N+ regions (contacts) 34 and N-well 38 may be formed by conventional ion implantation processes. In a conventional ion implantation process, a concentration of a dopant of certain conductivity type may be introduced into the semiconductor substrate 22.

By way of example, in the conventional ion implantation process, respective patterned implantation masks may be used to define selected areas exposed for the implantations. The implantation mask used to select the exposed area for forming the p-type structures is stripped after implantation, and before the implantation mask used to form the n-type structures of a different conductivity type (or vice versa). The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The P− type features, e.g., buried isolation layer 24, P− drift region 26, P− well 28, and P+ regions 18a, 30 may be doped with p-type dopants, e.g., Boron (B); whereas the drift region 14a, N-well 32, N+ regions (contacts) 34 and N-well 38 may be doped with n-type dopants, e.g., Arsenic (As), Phosphorus (P) and Antimony (Sb), among other suitable examples.

The shallow trench isolation structures 16, 36 can be formed by conventional lithography, etching and deposition methods known to those of skill in the art. For example, a resist formed over the semiconductor substrate 22 is exposed to energy (light) and developed utilizing a conventional resist developer to form a pattern (openings). An etching process with a selective chemistry, e.g., reactive ion etching (RIE), will be used to transfer the pattern to the semiconductor substrate 22 to form one or more trenches in semiconductor substrate 22. Following the resist removal by a conventional oxygen ashing process or other known stripants, insulator material (e.g., SiO₂) can be deposited by any conventional deposition processes, e.g., chemical vapor deposition (CVD) processes. Any residual material on the surface of the semiconductor substrate 22 can be removed by conventional chemical mechanical polishing (CMP) processes.

Wiring structures 42 may be provided to the emitter region 18, the base region 14 and the collector region 20. The wiring structures 42 may be formed by conventional lithography, etching and deposition methods as are known in the art such that no further explanation is required for a complete understanding of the present disclosure. As also should be understood by those of skill in the art, the wiring structures 42 may be formed in interlevel dielectric material, e.g., oxide, nitride or combinations thereof.

Prior to forming the wiring structures 42, a silicide process may be performed to form silicide contacts on the polysilicon material 40, N+ region (e.g., contact) 34 and P+ regions (e.g., contacts) 18a, 30. The reference numerals depicting the polysilicon material 40, N+ region (e.g., contact) 34 and P+ regions 18a, 30 may also be used to identify the silicide contacts.

As should be understood by those of skill in the art, the silicide process begins with deposition of a thin transition metal layer, e.g., nickel, cobalt or titanium, over fully formed and semiconductor devices (e.g., doped or ion implanted regions and polysilicon material 40). After deposition of the material, the structure is heated allowing the transition metal to react with exposed silicon (or other semiconductor material as described herein) in the active regions of the semiconductor device (e.g., doped or ion implanted regions and polysilicon material 40) forming a low-resistance transition metal silicide. Following the reaction, any remaining transition metal is removed by chemical etching, leaving silicide contacts in the active regions of the device.

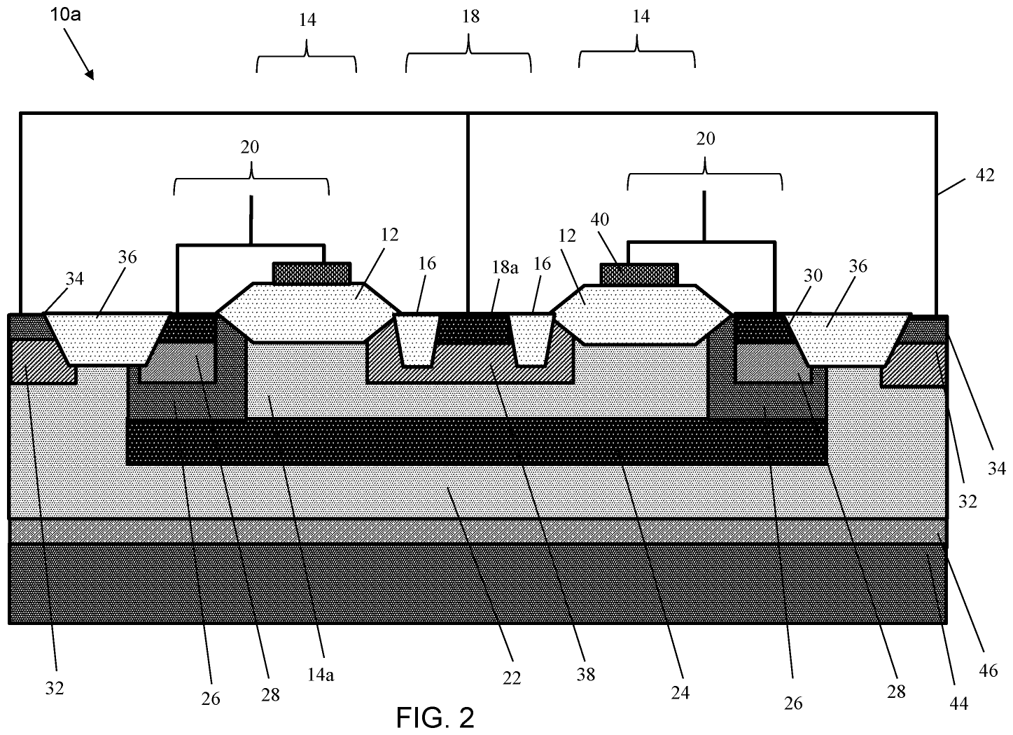

FIG. 2 shows a structure according to additional aspects of the present disclosure. More specifically, the structure 10a of FIG. 2 shows the structure 10 of FIG. 1 on a p-type semiconductor substrate 44. The p-type semiconductor substrate 44 may be isolated from the semiconductor substrate 22 by a buried isolation layer 46. In embodiments, the buried isolation layer 46 may be an N+ buried isolation layer. The buried isolation layer 46 may be formed by either an ion implantation process or an epitaxial growth process with an in-situ doping. As to the former configuration, the buried isolation layer 46 may be formed by an ion implant process into the semiconductor substrate 44. As to the latter configuration, the epitaxial growth process may be used to grow the buried isolation layer 46 and the semiconductor substrate 22 using the same semiconductor material, with a heavier n-type dopant concentration for the buried isolation layer 46. The remaining features of the structure 10a are similar to the structure 10 of FIG. 1.

Examples of various epitaxial growth processes that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth process can be performed utilizing any well-known precursor gas or gas mixture, e.g., hydrogen, nitrogen, helium and argon. A dopant (n-type as noted herein) is typically added to the precursor gas or gas mixture. An annealing process may be performed to drive in the dopant into the semiconductor substrate 22.

The p-type semiconductor substrate 44 may be a bulk handle substrate or semiconductor-on-insulator (SOI) technology. In the SOI technology, from top to bottom, a top semiconductor layer is provided over a buried insulator layer, which is provided over a handle substrate. The handle substrate and top semiconductor layer may be semiconductor material such as, for example, Si, Ge, SiGe, SiC, SiGeC, a III-V compound semiconductor, an II-VI compound semiconductor or any combinations thereof. Typically, the handle substrate and the top semiconductor layer comprises a single crystalline semiconductor material, such as, for example, single crystalline silicon with any suitable crystallographic orientation (e.g., a<100>, <110>, <111>, or <001>crystallographic orientation). The buried insulator layer may include a dielectric material such as silicon dioxide, silicon nitride, silicon oxynitride, boron nitride or a combination thereof. In one embodiment, the buried insulator layer may be a buried oxide layer (BOX).

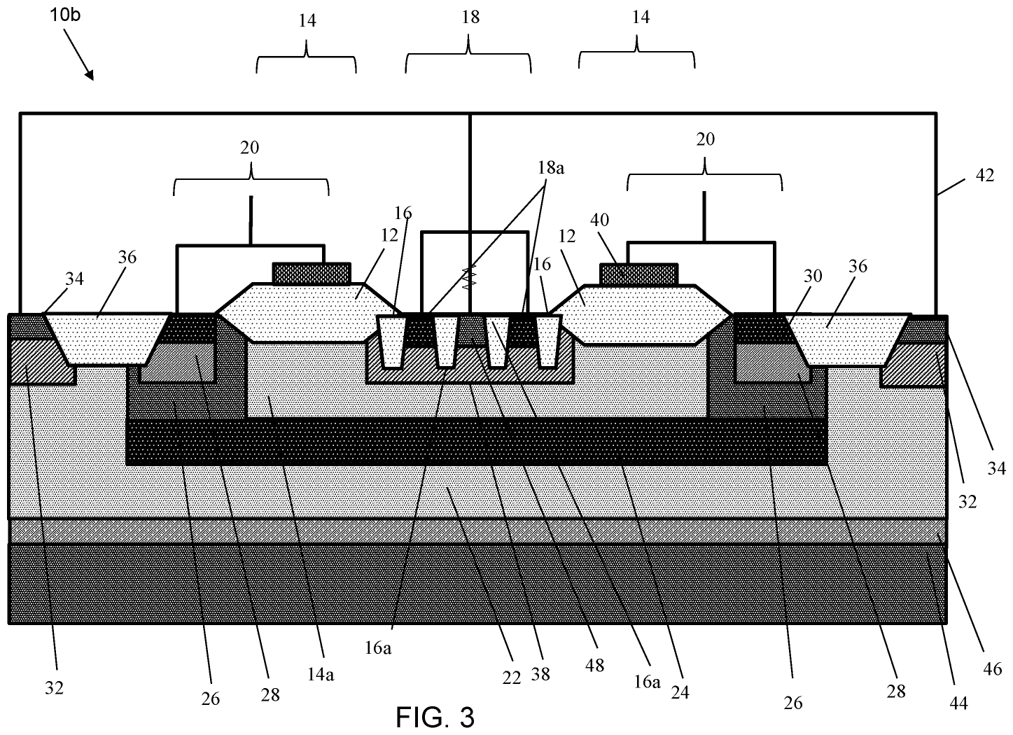

FIG. 3 shows a structure according to additional aspects of the present disclosure. More specifically, the structure 10b of FIG. 3 shows the structure 10a of FIG. 2 with a resistive element in the emitter region 18. More specifically, the resistive element includes an N+ region 48 in the N-well 38, separated from the P+ regions 18a by additional shallow trench isolation structures 16a. The N+ region 48 and the P+ regions 18a in the N-well 38 are electrically connected together by the wiring structures 42. The remaining features of the structure 10b are similar to the structure 10a of FIG. 2 such that no further explanation is required for a complete understanding of the present disclosure.

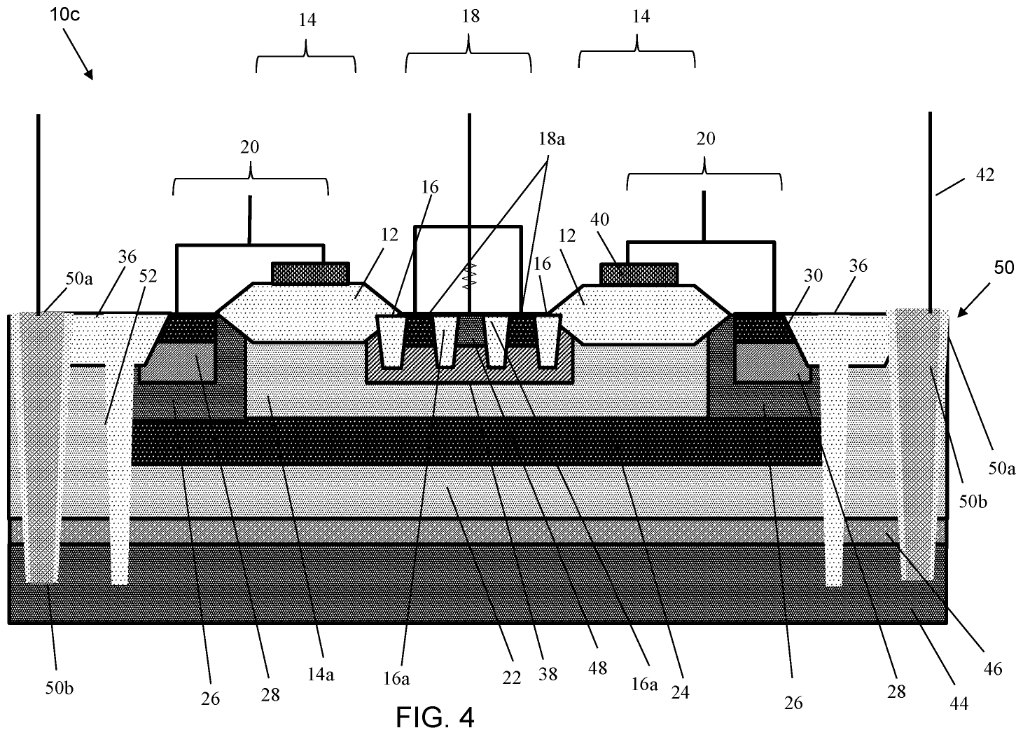

FIG. 4 shows another structure in accordance with further aspects of the present disclosure. The structure 10c of FIG. 4 includes a deep trench structure 50 and a deep trench isolation structure 52. The deep trench structure 50 and the deep trench isolation structure 52 may be formed by conventional lithography, etching and deposition methods as described herein such that no further explanation is required for a complete understanding of the present disclosure. In the structure 10c of FIG. 4, the N-wells 32 and N+ region 34 may be eliminated.

The deep trench structure 50 and the deep trench isolation structure 52 both extend to the underlying p-type semiconductor substrate 44. In addition, the deep trench isolation structure 52 extends through the shallow trench isolation structure 36, adjacent to and, in embodiments, contacting the p-type drift region 26. In this way, the emitter region 18, the collector region 20 and the base region 14 may be isolated using the buried isolation layer 24 and the deep trench isolation structure 52.

In embodiments, the deep trench structure 50 provides contact to a sub-collector region of the device. The deep trench structure 50 includes a sidewall liner comprising insulator material 50a (e.g., SiO₂) and polysilicon material 50b, e.g., p-type polysilicon, extending to the p-type semiconductor substrate 44. The wiring structure 42 may connect to the polysilicon material 50b, e.g., p-type polysilicon. The deep trench isolation structure 52 comprises insulator material, e.g., SiO₂. The remaining features of the structure 10c are similar to the structure 10b of FIG. 3 such that no further explanation is required for a complete understanding of the present disclosure.

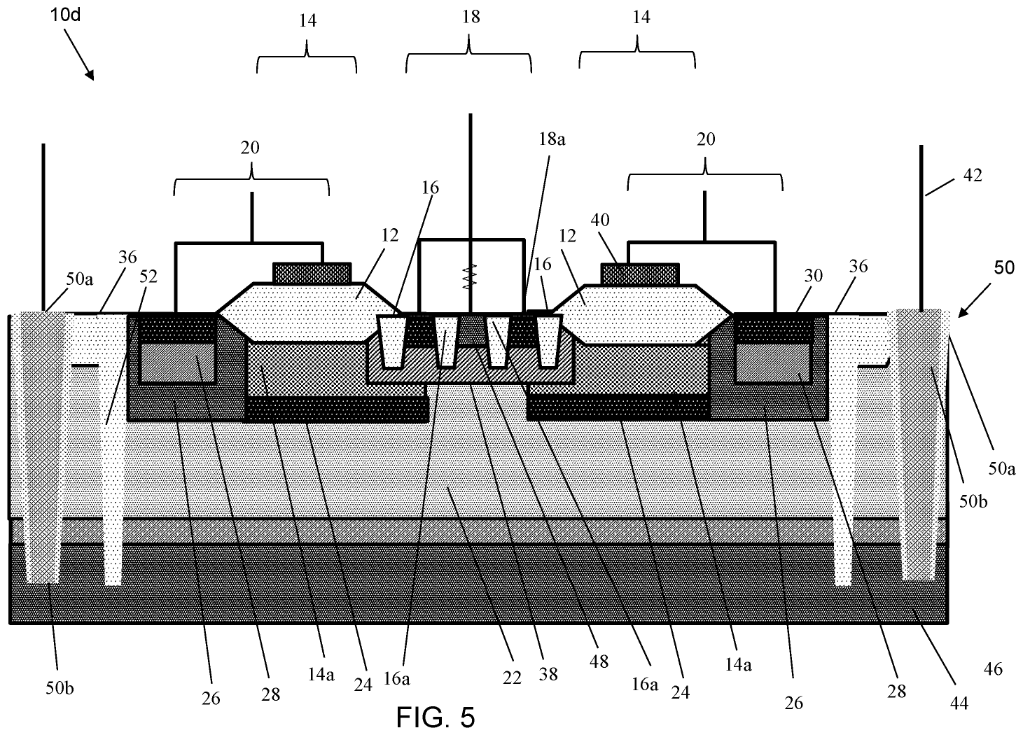

FIG. 5 shows yet another structure in accordance with aspects of the present disclosure. The structure 10d of FIG. 5 includes separate drift regions 14a in the base region 14. The drift regions 14a are isolated using separate buried isolation layers 24, e.g., P+ buried isolation layers. The remaining features of the structure 10d are similar to the structure 10c of FIG. 4 such that no further explanation is required for a complete understanding of the present disclosure.

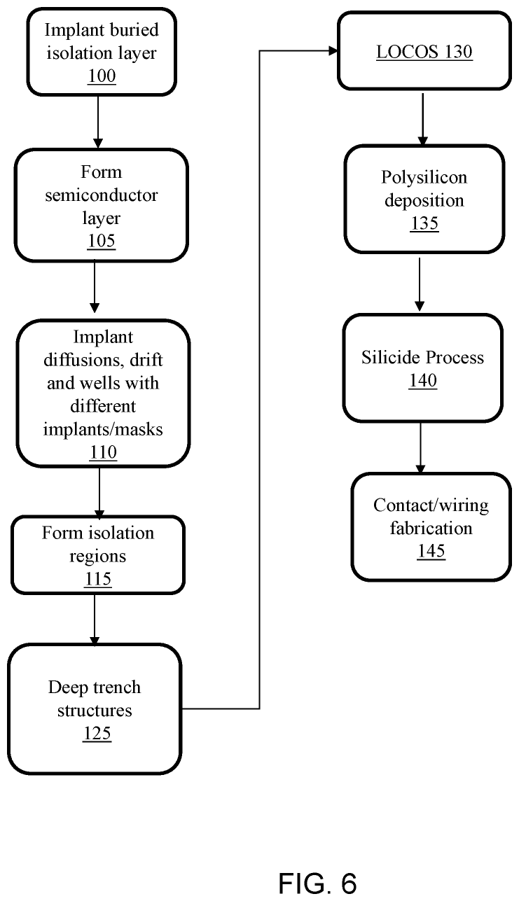

FIG. 6 shows a process flow representative of fabrication processes for manufacturing the devices of FIGS. 1-5. It should be understood that the steps of the process flow may be provided in a different order than provided herein, depending on available tooling and other design and process flow variables as are known in the art.

At step 100, the buried isolation layer 46 may be formed in the semiconductor substrate 44. In embodiments, the buried isolation layer 46 may be formed by an ion implantation process as already noted with respect to FIG. 2.

At step 105, the semiconductor material 22 may be epitaxially grown on the semiconductor substrate 44, over the buried isolation layer 46. In embodiments, the epitaxial growth of the semiconductor material 22 may include an in-situ doping with N-type dopants, e.g., arsenic.

At step 110, the buried isolation layer, diffusion regions, drift regions and implanted regions 18a, 24, 26, 28, 30, 32, 34, 38, 48 may be formed using separate ion implantation processes with different masks as described herein and known in the art such that no further explanation is required for a complete understanding of the present disclosure. In these processes, respective patterned implantation masks may be used to define selected areas exposed for the implantations. The implantation mask used to select the exposed area for forming a single feature is stripped after implantation, and before the implantation mask used to form another feature as is known in the art.

At step 120, the isolation structures 16, 16a, 36 are formed in the semiconductor material 22. In embodiments, the isolation structures 16, 16a, 36 may be shallow trench isolation structures formed by conventional lithography, etching and deposition methods as already described herein.

At step 125, optional deep trench structures 50, 52 may be formed through the semiconductor material 22, extending into the semiconductor material 44. The deep trench structures 50, 52 may be formed by conventional lithography and etching processes, followed by a deposition of insulator material and polysilicon material using a conventional deposition process, e.g., CVD. The deep trench isolation structure 50 may include a step of lining the structure with oxide material 50a followed by anisotropic etching process to remove the insulator from a bottom of the trench. The remaining portion of the deep trench isolation structure may be filled p-doped polysilicon material 50b using a conventional deposition method, e.g., CVD.

At step 130, the LOCOS 12 may be formed abutting to and in direct contact with the shallow trench isolation structures 16. In the LOCOS process, for example, a silicon oxide insulating structure penetrates under the surface of the semiconductor substrate 22 so that an Si—SiO₂ interface occurs at a lower point than the rest of the silicon surface. The LOCOS process includes a thermal oxidation process at selected regions. In this process, the oxygen penetrates in depth of the semiconductor substrate 22, reacts with silicon (or other semiconductor material) and transforms it into, for example, silicon oxide. The LOCOS will be partially extending underneath a surface and within the semiconductor substrate 22, and partially above the surface of the semiconductor substrate 22.

At step 135, polysilicon material 40 may be deposited on the LOCOS 12. The polysilicon material 40 may be epitaxially grown or deposited using conventional deposition methods, e.g., CVD processes, followed by a conventional patterning process.

At step 140, the silicide contacts may be formed using conventional silicide processes as described herein. The silicide may be formed on any of the active regions, e.g., diffusion regions and polysilicon material.

At step 145, the wiring structures (e.g., metal contacts) 42 may be formed using conventional lithography, etching and deposition processes. For example, the wiring structures 42 may be fabricated by forming a via in an interlevel dielectric material, following by deposition of metal material, e.g., tungsten, aluminum, copper, etc., and followed by a chemical mechanical polishing (CMP) process as is known in the art such that no further explanation is required herein for a complete understanding of the present disclosure.

The structures described herein can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprises:
a device comprising a collector region, an emitter region, and a base region;
an oxidation structure within the base region; and
an isolation structure abutting the oxidation structure and extending between the base region and the emitter region.

2. The structure of claim 1, wherein the oxidation structure comprises a local oxidation (LOCOS) in a semiconductor substrate in the base region.

3. The structure of claim 2, wherein the oxidation structure is a raised isolation structure above a surface of the semiconductor substate and extending below the surface of the semiconductor substrate.

4. The structure of claim 2, further comprising polysilicon material on the oxidation structure.

5. The structure of claim 4, wherein the polysilicon material electrically connects to a diffusion region in the collector region.

6. The structure of claim 1, wherein the oxidation structure extends between a diffusion region in the collector region and contacts the isolation structure.

7. The structure of claim 6, wherein the diffusion region comprises a p-type dopant within a P− well and a P− drift region.

8. The structure of claim 7, further comprising a P+ buried isolation layer in a semiconductor substrate, wherein the P− drift region and the P+ buried isolation layer isolate an N+ drift region of the base region.

9. The structure of claim 2, wherein the isolation structure comprises a shallow trench isolation structure extending within a first well of a first conductivity type and is adjacent to a diffusion region of a second conductivity type within the first well.

10. The structure of claim 9, wherein the first conductivity type comprises an n-type dopant and the second conductivity type comprises a p-type dopant.

11. The structure of claim 9, further comprising a resistive element comprising a diffusion region of the first conductivity type between the diffusion region of the second conductivity type within the first well.

12. The structure of claim 11, wherein the diffusion region of the first conductivity type is isolated from the diffusion region of the second conductivity type by a shallow trench isolation structure.

13. The structure of claim 1, further comprising a deep trench isolation structure comprising an insulator lining material and filled polysilicon material and a second deep trench isolation structure comprising insulator material, the second deep trench isolation structure isolating the emitter region, the collector region and the base region.

14. The structure of claim 13, wherein the polysilicon material comprises P− doped polysilicon and extends to an underlying semiconductor substrate beneath an N+ buried layer.

15. A structure comprising:
a collector region comprising a P− drift region in a semiconductor substrate;
an emitter region comprising a P+ diffusion region in an N-well and a shallow trench isolation structure adjacent to the P+ diffusion region;
a base region within an N-drift region in the semiconductor substrate; and
a local oxidation in the base region, extending from the P− drift region and contacting the shallow trench isolation structure.

16. The structure of claim 15, wherein the local oxidation in the base region is raised above a top surface of the semiconductor substrate and extends below the top surface of the semiconductor substrate.

17. The structure of claim 15, further comprising P− doped polysilicon on the local oxidation and electrically connecting to a P+ diffusion region within the P− drift region.

18. The structure of claim 15, further comprising:
a first deep trench isolation structure touching the P− drift region and extending into an underlying substrate below a buried isolation layer; and
a second deep trench isolation structure extending into the underlying substrate below the buried isolation layer, wherein the second deep trench isolation structure comprises an insulator liner and a polysilicon material.

19. The structure of claim 15, further comprising a resistive element comprising an N+ diffusion region within the N-well and isolated from the P+ diffusion region by shallow trench isolation structures in the N-well.

20. A method comprises:
forming a device comprising a collector region, an emitter region, and a base region;
forming an oxidation structure within the base region; and
forming an isolation structure abutting the oxidation structure and extending between the base region and the emitter region.
